(19) United States
(12) Patent Application Publication
(10) Pub. No.: US 2026/0226651 A1
(43) Pub. Date: Aug. 6, 2026

(54) DEVICE FOR MANUFACTURING SCINTILLATORS, METHOD OF MANUFACTURE THEREOF

(71) Applicant: Siemens Medical Solutions USA, Inc., Malvern, PA (US)

(72) Inventor: Mark Andreaco, Knoxville, TN (US)

(21) Appl. No.: 19/157,487

(22) PCT Filed: May 31, 2023
(86) PCT No.: PCT/US2023/067663

§ 371 Date: Aug. 18, 2025

(51) Int. Cl. C30B 15/14; C30B 29/34

(52) U.S. Cl. CPC C30B 15/14; C30B 29/34

(57) ABSTRACT

Disclosed herein is a device for manufacturing a single crystal comprising a furnace that includes a furnace wall; a quartz tube disposed concentrically within the furnace wall; an induction coil disposed in an annulus between the quartz tube and the furnace wall; a crucible disposed at a bottom surface of the furnace within the quartz tube; where the crucible includes a wall extending upward from a bottom crucible surface; and a refractory lining being disposed in an annulus between the quartz tube and the crucible; where a portion of the refractory lining has a different composition, property, geometry, or a combination thereof from the A remainder of the crucible.

### BACKGROUND

This disclosure relates to a device for manufacturing scintillators and a method of manufacturing the device. In particular, this disclosure relates to a furnace for crystal growth that reduces impurities incorporated in the crystal lattice during a high temperature oxide crystal growth process. The crystals are used in positron emission tomography (PET) scintillation detectors.

In the manufacturing of a high temperature oxide crystals such as those from lutetium orthosilicates (LSO), lutetium yttrium silicates (LYSO), gadolinum aluminum gallium garnets (GAGG), and the like, powders in the appropriate stoichiometric ratios are taken in a crucible and heated to form a melt. The melt is then contacted with a seed crystal which is gradually extracted from the melt to form the crystal.

During this process of manufacturing the single crystal it is desirable for the dopants in the melt to be evenly distributed so that their distribution in the crystal boule is uniform. However, this is typically not the case. The dopants tend to migrate to the surface of the melt and congregate in the center of the crystal boule. It is also desirable for impurities to not be incorporated in the boule. However, this is typically not the case.

Due to the geometrical symmetry of the furnace and the thermal field it produces, a convection flow of the melt produces a cold spot in the center of the crucible, creating a location at which impurities can collect. The convection flow of the melt with the cold spot in the center is produced as a result of a symmetrical flow field in the furnace due of geometrical symmetry within the furnace. Since the seed crystal contacts the melt in the center (i.e., at the cold spot), the impurities tend to become incorporated into the boule. There is therefore a need to find a method to minimize impurity concentration at the center of the crystal boule during the production of a single crystal.

It is desirable to create a flow field in the crucible that moves impurities away from a location at which a seed crystal contacts the melt.

### SUMMARY

Disclosed herein is a device for manufacturing a single crystal comprising a furnace that includes a furnace wall; a quartz tube disposed concentrically within the furnace wall; an induction coil disposed in an annulus between the quartz tube and the furnace wall; a crucible disposed at a bottom surface of the furnace within the quartz tube; where the crucible includes a wall extending upward from a bottom crucible surface; and a refractory lining being disposed in an annulus between the quartz tube and the crucible; where a portion of the refractory lining has a different composition, property, geometry, or a combination thereof from the remainder of the crucible.

Disclosed herein is a method of growing a single crystal, comprising disposing a crucible within a furnace; where the crucible contains a melt that is operative to produce a single crystal; a refractory lining being disposed in the furnace and surrounding the crucible; where a portion of the refractory lining has a different composition, property, geometry, or a combination thereof from the remainder of the crucible; heating the melt within the crucible, wherein the different composition, property, geometry, or the combination thereof produces a thermal gradient within the melt to draw a cold spot of a convection cell of the melt away from a seed location in the crucible; and drawing a crystal boule from the seed location of the crucible to grow the single crystal.

Disclosed herein too is a high purity crystal boule comprising lutetium orthosilicate, lutetium yttrium orthosilicate, gadolinum gallium garnet or gadolinum aluminum gallium garnet, where the crystal boule is prepared by a method comprising disposing a crucible within a furnace; where the crucible contains a melt that is operative to produce a crystal boule of lutetium orthosilicate, lutetium yttrium orthosilicate, gadolinum gallium garnet, gadolinum aluminum gallium garnet; disposing a refractory lining in the furnace and surrounding the crucible; where a portion of the refractory lining has a different composition, property, geometry, or a combination thereof from the remainder of the crucible; heating the melt within the crucible, wherein the different composition, property, geometry, or the combination thereof produces a thermal gradient within the melt to draw a cold spot of a convection cell of the melt away from a seed location in the crucible; and drawing the crystal boule from the seed location of the crucible.

### BRIEF DESCRIPTION OF THE FIGURES

FIG. 1 is an exemplary depiction of the furnace with a crucible disposed therein;

FIG. 2 is an exemplary depiction of the flow field of the melt in the crucible;

FIG. 3 is an exemplary top-view depiction of the refractory lining around the crucible which causes the cold spot in the melt to move from the crucible center to an off-center location;

FIG. 4A is another exemplary top-view depiction of the refractory lining around the crucible which causes the cold spot in the melt to move from the crucible center to an off-center location; and

FIG. 4B is an exemplary side-view depiction of the refractory lining disposed around the crucible; where the refractory lining has holes that facilitate a movement of the cold spot in the melt to an off-center location.

### DETAILED DESCRIPTION

The present invention may be understood more readily by reference to the following detailed description of preferred embodiments of the invention as well as to the examples included therein. All numeric values are herein assumed to be modified by the term “about,” whether or not explicitly indicated. The term “about” generally refers to a range of numbers that one of skill in the art would consider equivalent to the recited value (i.e., having the same function or result). In many instances, the term “about” may include numbers that are rounded to the nearest significant figure.

Disclosed herein is a method for creating crystal boules that have a reduced amount of impurities. Disclosed herein too are crystalline boules that contain a lower percentage of impurities than the boules produced by other methods. During the production of crystalline boules, the symmetrical location of the induction coils in the furnace (around the crucible) produces symmetrical thermal fields in the melt (contained in the crucible). The symmetrical thermal field results in the formation of a symmetrical convection flow of the melt, which in turn results in the formation of a cold spot in the center of the melt. The cold spot contains a higher percentage of undesirable impurities than the surrounding melt. Since the pull rod contacts the cold spot during the production of the crystal boule, these impurities get incorporated into the crystal boule. Put another way, the formation of a centrally located cold spot promotes the migration of impurities to the center of the boule. Since the seed contacts the melt at the cold spot to create a nucleation point this results in a concentration of impurities in the crystal boule.

This situation can be alleviated by changing the thermal symmetry of the furnace which in turn creates an asymmetrical flow field in the crucible. This results in impurities concentrating at a point in the melt that is located away from the point at which the seed contacts the melt. The method disclosed herein promotes the migration of dopants to preferential off-center regions of the boule by creating a convection pathway in the boule. This is accomplished by creating a thermal pathway in the circular refractory lining that is placed between the crucible and the quartz tube that lies inside the induction coils. The cold spot can thus be moved away from the center towards the crucible wall and can occur further from the center and more proximate to the wall of the crucible if desired. By moving the cold spot, the impurities will not be located at the point that the seed contacts the melt and hence will not be incorporated into the crystal boule.

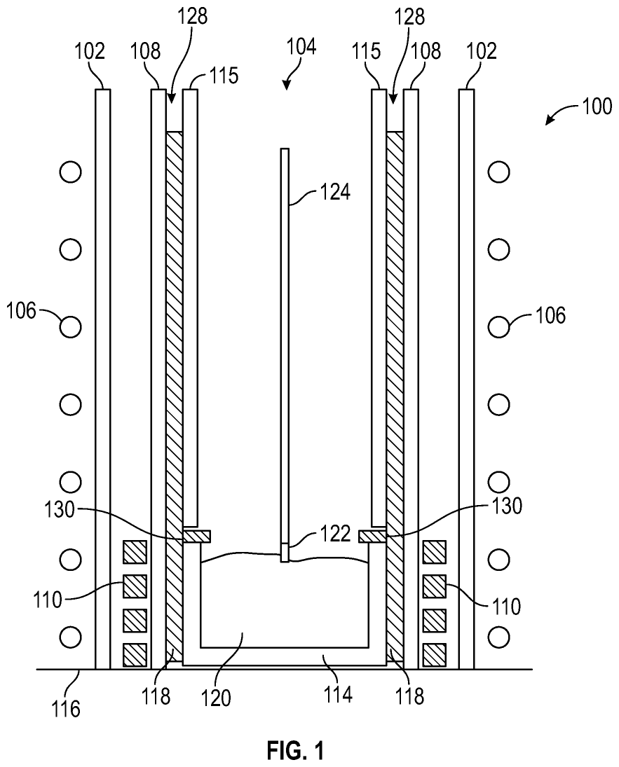

FIG. 1 is a side view of a furnace 100 in which a boule is grown, in an illustrative embodiment. The furnace 100 includes a furnace wall 102 enclosing a space 104. A copper coil 106 is wrapped around an outer surface of the furnace wall 102. Water or coolant flows through the copper coil 106 to carry heat away from the furnace 100 or maintain a temperature in the space 104 within the furnace 100. A quartz tube 108 is disposed concentrically within the furnace wall 102. An induction coil 110 disposed is in an annulus between the quartz tube 108 and the furnace wall 102. A crucible 114 is placed at a bottom surface 116 of the furnace 100 within the quartz tube 108. The crucible 114 includes a cylindrical wall extending upward from a bottom crucible surface. The crucible 114 can be made of iridium. The crucible 114 extends partway up the furnace 100 from the bottom surface 116. A brick refractory cylinder or ceramic cylinder 115 extends from a top of the crucible 114 to a top or lid 130 of the furnace 100. A refractory lining 118 is disposed in an annulus 128 between the quartz tube 108 and the crucible 114/brick cylinder 115.

To make a boule, ingredients for forming a melt 120 are disposed in the crucible 114 and the crucible 114 is placed concentrically within the furnace 100. The induction coil 110 is activated to heat the ingredients to form the melt 120. A seed crystal 122 is lowered through the brick cylinder 115 at an end of a rod 124 to contact a top of the melt 120 at a seed location (i.e., a location at which the boule is to be drawn from the melt). The seed crystal 122 is then drawn upward from the melt 120, allowing the melt 120 to cool and crystallize around the seed crystal 122. Drawing the seed crystal 122 upward with simultaneous rotation of the seed crystal creates a boule or cylindrical crystal.

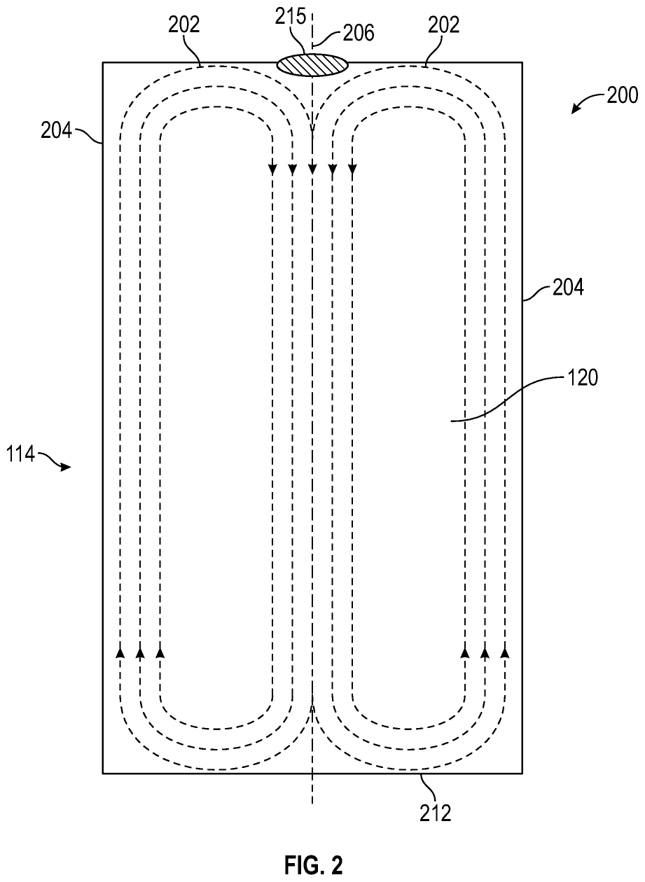

FIG. 2 shows a side view 200 of the crucible during a heating of the melt. Convection cells 202 form in the melt 120 when the melt is heated above a given temperature. The heat at the wall 204 of the crucible 114 causes the melt 120 to flow upward at the wall 204. Upon reaching the top of the crucible 114, the melt 120 migrates radially inward toward a central axis 206 of the crucible 114, cooling in the process. A cold spot 215 thus develops at the top of the melt at the central axis 206. Impurities will tend to collect at the cold spot 215. The melt 120 then descends to the bottom of the crucible 114 along the central axis 206. The method disclosed herein creates a thermal gradient in the melt to move the cold spot 215 away from the central axis 206.

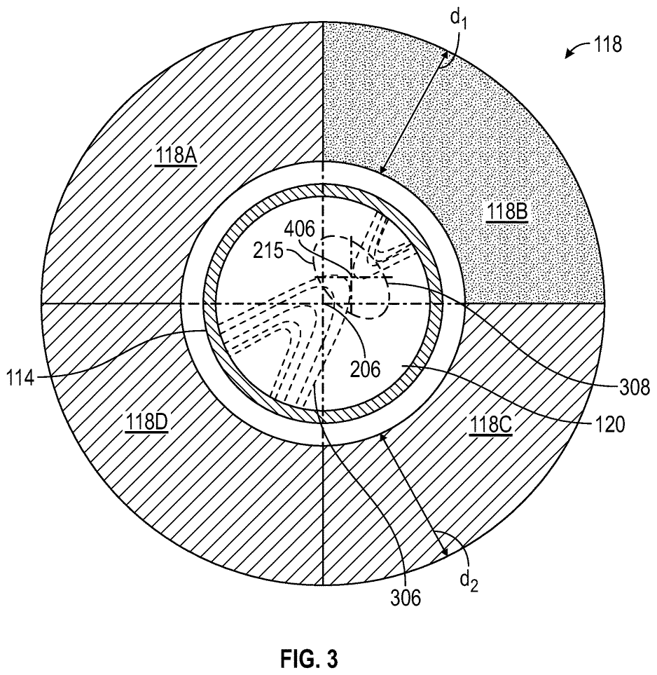

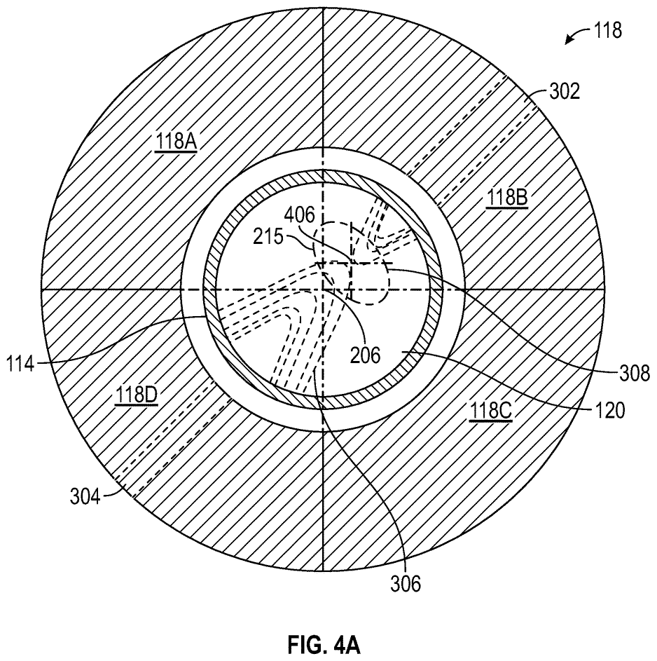

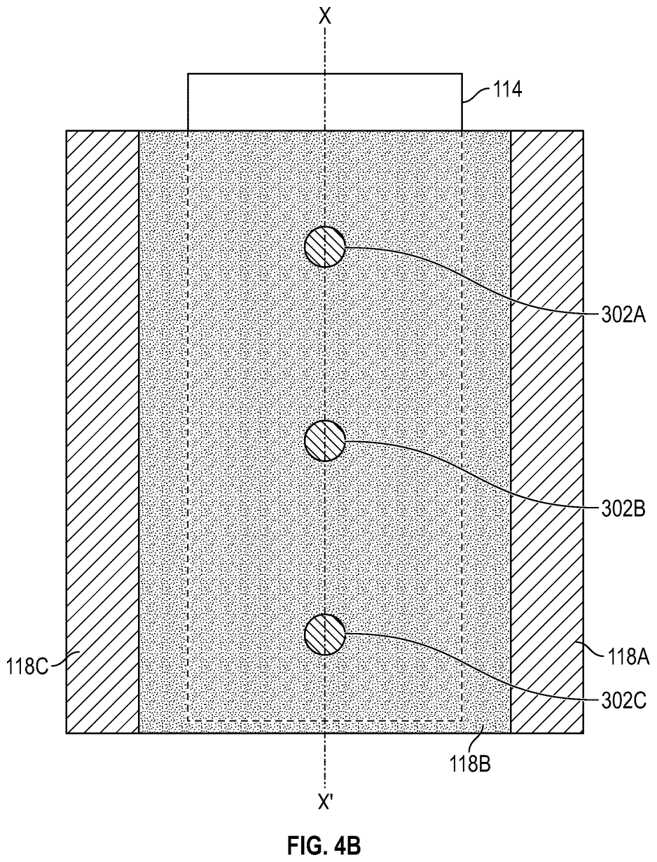

FIGS. 3 and 4 depict one method of moving the cold spot 215 away from the central axis 206. The method comprises changing the material composition, material property, geometry, or a combination thereof of at least one portion of the refractory lining 118 that surrounds the crucible 114. The change in the thermal conductivity may be arrived at by either a change in the cross-sectional geometry, thermal property or chemical composition of a portion of the refractory lining 118 or even removal of a part of the lining as compared with the remainder of the refractory lining. This change in the refractory lining converts a symmetrical thermal field to an asymmetrical thermal field and results in a movement of the cold spot from the center of the crucible to a spot closer to the crucible walls.

In an embodiment, the different composition, property, geometry, or the combination thereof produces a thermal gradient within the melt to draw a cold spot of a convection cell of the melt away from a seed location in the crucible. The crystal boule is then drawn from the usual seed location of the crucible (which is in the center) to grow the single crystal.

The portion of the refractory lining that is different from the remainder of the refractory lining may be 2 to 25%, preferably 5 to 15% of the total volume of the refractory lining.

In one embodiment, the method comprises changing the material composition of one or more portions of the refractory lining 118 as compared with the remainder of the refractory lining. In another embodiment, the method comprises changing the geometry of a portion of the refractory lining 118 as compared with the remainder of the refractory lining. All of these embodiments are discussed in detail below.

FIGS. 3, 4A and 4B depict these concepts by showing only a portion of the furnace for the sake of simplicity. FIG. 3 depicts only the crucible 114 with the melt 120 contained therein and the refractory lining 118 that surrounds the crucible 114. When the refractory lining 118 is uniform property-wise or geometry-wise and is symmetrically disposed about the crucible and the induction coils (not shown in the FIGS. 3, 4A and 4B), the cold spot occurs in the central axis 206 of the crucible 114 (and hence the melt 120). This is because the distribution of heat is symmetrical in the furnace (not shown). The symmetrical thermal field in the melt 120 (in the crucible 114) causes the cold spot to be centrally located at central axis 206.

In an embodiment depicted in the FIG. 3, the refractory lining 118 comprises 4 quadrants 118A, 118B, 118C and 118D. These quadrants may have locating elements (not shown) on each one of them that permits them to be assembled to form a concentric tubular layer of insulation in the annulus 128 (see FIG. 2) that surrounds the crucible 114. In an embodiment, one of the 4 quadrants may be manufactured from a material that has a different thermal conductivity than the other quadrants. The FIG. 3 depicts a quadrant 118B that comprises a material having a different thermal conductivity from the quadrants 118A, 118C and 118D. The quadrant 118B comprises a first material having a first thermal conductivity, while the quadrants 118A, 118C and 118D each comprise a second material having a second thermal conductivity, where the second thermal conductivity is different from the first thermal conductivity. It is to be noted that while the refractory lining 118 has been described in terms of fractional units that comprise quadrants, other fractional units such as halves, thirds, one-fifths, one-sixths, and so on may be used to form the entire refractory lining.

The first material and the second material are different from one another but be selected from a group of refractory materials consisting of alumina, zirconia, yttria-stabilized zirconia (YSZ), graphite, silica, magnesia, lime, silicon carbide, tungsten carbide, boron nitride, hafnium carbide, molybdenum disilicide, tantalum hafnium carbide, or a combination thereof. Alumina and zirconia are preferred refractory materials.

In an embodiment, the quadrant 118B may comprise alumina while the quadrants 118A, 118C and 118D each comprise zirconia. In another embodiment, the quadrant 118B may comprise zirconia while the quadrants 118A, 118C and 118D each comprise alumina. Using one quadrant that comprises a different material from the other quadrants helps facilitate a movement of the cold spot away from the central axis 206.

Using one quadrant (or portion) that has a different material composition from the other quadrants (or portions) causes a shift in the cold spot 215 to an off-center location 406. This is because the different thermal conductivity of the quadrant 118B from the other quadrants 118A, 118C or 118D causes an asymmetrical thermal field in the crucible 114, which causes the cold spot 215 to migrate from the central axis 206 (a concentric location with regard to the crucible 114) to an off-center location 406 (which is an eccentric location with regard to the crucible 114) and circumscribed by dotted ellipse 308.

When the seed crystal at the end of the pull rod is dipped into the melt at the center of the melt (which lies along central axis 206) it no longer contacts the cold spot (which has since migrated to an off-center location 406) and the impurities which typically get incorporated into the crystal boule no longer are incorporated into the boule.

In another embodiment, the cold spot may be moved from the central axis 206 to an off-center location by having one of the portions of the refractory lining have different thermal conductivity characteristics even though the material composition is the same as the other portions of the refractory lining. For example, with reference to the FIG. 3, all of the quadrants 118A, 118B, 118C and 118D can comprise the same material (e.g., zirconia or alumina). However, the quadrant 118B may have a different porosity from the quadrants 118A, 118C and 118D. In other words, the bulk density of quadrants 118B may be different from those of quadrants 118A, 118C and 118D. This difference in porosity promotes a thermal asymmetry in the crucible 114, which causes the cold spot to migrate from the central axis 206 (a concentric location with respect to the crucible 114) to off-center location 406 (an eccentric location with respect to the crucible 114).

The choosing of a portion of the refractory lining to be different from other portions (either in composition or in physical properties may therefore be used to facilitate moving the cold spot from a central to an off-center location, thus minimizing the incorporation of impurities into the crystal boule.

A portion of the refractory lining may have a different geometry from the remainder of the refractory lining. The difference in geometry may include a change in size, shape of cross-sectional area, or a combination thereof. The change in cross-sectional area includes a difference in a shape of a cross-section taken either in horizontal plane or vertical plane through a portion of the refractory lining.

As seen in the FIG. 3, each quadrant 118A, 118B, 118C and 118D have a radial thickness of di. In an embodiment, one of the quadrants (such as, for example 118B) may have a radial thickness di that is less than the radial thickness de of each of the remaining quadrants 118A, 118C and 118D. This is not depicted in the FIG. 3, but can be easily envisioned by one of ordinary skill in the art. This difference in thickness of one of the quadrants leads to an asymmetrical thermal field, which in turn promotes any asymmetry in the melt flow field in the crucible and leads to the cold-spot being proximate to the wall rather than the center of the crucible.

In another embodiment, depicted in the FIGS. 4A and 4B, holes 302 or 304 are disposed in the refractory lining 118. The holes may be drilled in the refractory lining after it is manufactured. Alternatively, the refractory lining may be cast or molded with the holes being formed during the casting or molding. The holes 302 or 304 are oriented radially and extend throughout the thickness of the refractory lining 118 from the inner to outer surface. As noted above, the refractory lining 118 lies in the annulus 128 that is situated between the quartz tube 108 and the crucible 114. The presence of the holes 302 and 304 in the refractory lining changes the symmetry of the thermal field that surrounds the crucible 114 and promotes a change in the thermal symmetry of the melt 112.

A thermal pathway is created by providing holes in the refractory lining through which heat generated by the crucible can be dissipated. The holes are asymmetrical in some fashion or the other, which in turn creates an asymmetrical flow field. The portion of the crucible adjacent the hole is cooler than the surrounding portions of the crucible. This creates a convective pathway (also referred to as a cold finger) for the molten material contained in the crystal boule.

A hole or slot 302 can be formed in any one of the 4 quadrants to cause a change in the symmetry of the thermal field in the furnace. A deviation can be created in the thermal field (and hence the flow field) of the melt by creating one or more holes in one or more quadrants of the refractory lining. This deviation can be caused so long as the holes created in the refractory lining are not symmetrically distributed about the central axis 206.

For example, with reference to the FIG. 4A, a single hole 302 can be created in the quadrant 118B of the refractory lining. The presence of the hole will lead to a thermal field asymmetry in the melt and cause the cold spot to shift from the central axis 206 (of the crucible) to a new location 406 (and circumscribed by dotted ellipse 308) that is closer to the quadrant 118b that has the hole 302. The hole 302 may be a partial or complete hole, but its presence causes the heat distribution around the crucible to change. The heat distribution changes from symmetrical to asymmetrical leading to a movement of the cold spot to a location that is eccentric with respect to the center (the central axis 206) of the crucible. The cold spot is no longer concentric with regard to the geometry of the crucible, the refractory lining or with respect to the furnace.

More than one hole can be disposed in the refractory lining. For example, as seen in the FIG. 4A, a first hole 302 can be disposed in the quadrant 118B, while a second hole 304 (of a different size from that of the first hole 302) can be disposed in the quadrant 118D. A plurality of holes can be disposed in one or more quadrants of the refractory lining and these holes will promote the movement of the cold spot to an eccentric location so long as the holes are asymmetrically distributed about the crucible. For example, there can be more holes in the refractory lining on one side of the crucible as compared with the other side. Alternatively, the hole in the refractory lining on one side can be bigger than a hole or a plurality of holes on the other side.

FIG. 4B depicts another embodiment of the refractory lining that comprises a plurality of holes to produce a cold finger that facilitates a displacement of the cold spot. FIG. 4B depicts a side view of the crucible 114 with the refractory lining 118 disposed around it. One of the portions of the refractory lining may contain a plurality of holes 302A, 302B, 302C, and so on, from top to bottom to create the thermal finger that promotes the movement of the cold spot from the center (located along central axis 206) to an off-center location.

Since the cold spot is moved to an off-center location, the crystal seed no longer contacts the cold spot when extracting the crystal boule. In short, the asymmetry can be produced by tuning the holes in the refractory lining to move the center of the flow field away from the geometric center of the boule. The cold spot can be moved away from the center towards the walls and can occur at the walls of the crucible if desired. Impurities are removed from the center to prevent incorporation during nucleation by the seed and are excluded from the crystal boule. By moving the cold spot, the impurities will not be located at the seed.

In an embodiment, the method disclosed herein may be used to produce lutetium orthosilicates (LSO), lutetium yttrium orthosilicates (LYSO), gadolinum gallium garnets (GGG), gadolinum aluminum gallium garnets (GAGG), and the like, single crystal boules that contain a smaller percentage of impurities. The single crystal boules are greater than 99% pure, preferably greater than 99.5% pure and more preferably greater than 99.9% pure.

In an embodiment, a pixel obtained from the center of the crystal boule has a much lower impurity content than a pixel obtained from an outer surface of the crystal boule. The crystal boule is divided into a number of pixels and crystal boules produced by using the aforementioned method generally produces pixels that have less impurities when located at the center of the boule than when located at an outer surface of the boule. In other words, there is a gradient in purity from a center of the boule to and outer surface of the boule, with the center having a smaller amounts of impurities than the surface.

In an embodiment, using an asymmetrical melt field in the furnace results in a reduction of impurities in a crystal boule based on how much cerium and other desirable co-dopants were incorporated into the lattice of crystal. When using an asymmetrical flow field, changes in scintillation characteristics of crystals were observed indicating that less cerium and other desirable co-dopants uptake were incorporated into the crystal boule. This resulted in an understanding that if by using an asymmetrical flow field cerium and other desirable co-dopants were driven outside the center of the melt, then impurities in the melt could also be removed by contacting the melt with a seed crystal at a location away from the cold spot. Using this invention in the production process, it could be desirable to increase concentration of useful co-dopants (cerium for example) in the original mix of chemical constituents of the melt to compensate a diminished uptake of these desirable co-dopants.

While the invention has been described with reference to some embodiments, it will be understood by those skilled in the art that various changes may be made and equivalents may be substituted for elements thereof without departing from the scope of the invention. In addition, many modifications may be made to adapt a particular situation or material to the teachings of the invention without departing from essential scope thereof. Therefore, it is intended that the invention not to be limited to the particular embodiments disclosed as the best mode contemplated for carrying out this invention, but that the invention will include all embodiments falling within the scope of the appended claims.

What is claimed is:

1. A device for manufacturing a single crystal comprising:
a furnace that includes a furnace wall;
a quartz tube disposed concentrically within the furnace wall;
an induction coil disposed in an annulus between the quartz tube and the furnace wall;
a crucible disposed at a bottom surface of the furnace within the quartz tube; where the crucible includes a wall extending upward from a bottom crucible surface; and
a refractory lining being disposed in an annulus between the quartz tube and the crucible; where a portion of the refractory lining has a different composition, property, geometry, or a combination thereof from the remainder of the crucible.

2. The device of claim 1, where the remainder of the refractory lining has a uniform and consistent composition, property or geometry throughout its volume.

3. The device of claim 1, where the portion of the refractory lining comprises a volume of 2 to 25% of the total volume of the refractory lining.

4. The device of claim 1, where the refractory lining comprises alumina, zirconia, yttria-stabilized zirconia, graphite, silica, magnesia, lime, silicon carbide, tungsten carbide, boron nitride, hafnium carbide, molybdenum disilicide, tantalum hafnium carbide, or a combination thereof.

5. The device of claim 1, where the portion of the refractory lining comprises alumina and where the remainder of the refractory lining comprises zirconia.

6. The device of claim 1, where the portion of the refractory lining comprises zirconia and where the remainder of the refractory lining comprises alumina.

7. The device of claim 1, where the different property includes a difference in bulk density.

8. The device of claim 1, where the different property includes a difference in porosity.

9. The device of claim 1, where the different geometry includes having a different shape in cross-sectional area.

10. The device of claim 1, where the different geometry includes having a different cross-sectional thickness measured in the radial direction.

11. The device of claim 1, where the different geometry includes having one or more holes in at least one portion of the refractory lining; where at least one hole extends in a radial direction through the refractory lining.

12. The device of claim 1, where the different geometry includes having a plurality of holes in at least two portions of the refractory lining; and where the plurality of holes in one portion of the refractory lining are different in size from those in another portion of the refractory lining.

13. A method of growing a single crystal, comprising:
disposing a crucible within a furnace; where the crucible contains a melt that is operative to produce a single crystal;
a refractory lining being disposed in the furnace and surrounding the crucible; where a portion of the refractory lining has a different composition, property, geometry, or a combination thereof from the remainder of the crucible;
heating the melt within the crucible, wherein the different composition, property, geometry, or the combination thereof produces a thermal gradient within the melt to draw a cold spot of a convection cell of the melt away from a seed location in the crucible; and
drawing a crystal boule from the seed location of the crucible to grow the single crystal.

14. The method of claim 13, further comprising disposing a hole in at least a portion of the refractory lining to create the different geometry.

15. The method of claim 14, where the remainder of the refractory lining has a uniform and consistent composition, property or geometry throughout its volume.

16. The method of claim 14, where the portion of the refractory lining comprises alumina and where the remainder of the refractory lining comprises zirconia or vice versa

17. The method of claim 14, where the different geometry includes having a different shape in cross-sectional area.

18. The method of claim 14, where the different geometry includes having one or more holes in at least one portion of the refractory lining; where at least one hole extends in a radial direction through the refractory lining.

19. A high purity crystal boule comprising:
lutetium orthosilicate, lutetium yttrium orthosilicate, gadolinum gallium garnet or gadolinum aluminum gallium garnet, where the crystal boule is prepared by a method comprising:
disposing a crucible within a furnace; where the crucible contains a melt that is operative to produce a crystal boule of lutetium orthosilicate, lutetium yttrium orthosilicate, gadolinum gallium garnet, gadolinum aluminum gallium garnet;
disposing a refractory lining in the furnace and surrounding the crucible; where a portion of the refractory lining has a different composition, property, geometry, or a combination thereof from the remainder of the crucible;
heating the melt within the crucible, wherein the different composition, property, geometry, or the combination thereof produces a thermal gradient within the melt to draw a cold spot of a convection cell of the melt away from a seed location in the crucible; and
drawing the crystal boule from the seed location of the crucible.

20. The crystal boule of claim 19, where the seed location in the crucible is in a center of the melt in the crucible.
